(19) United States
(12) Patent Application Publication
(10) Pub. No.: US 2025/0022735 A1
(43) Pub. Date: Jan. 16, 2025

(54) OVERHEAD CONVEYING VEHICLE

(71) Applicant: MURATA MACHINERY, LTD., Kyoto-shi, Kyoto (JP)

(72) Inventors: Makoto Kobayashi, Ise-shi, Mie (JP); Kazuya Aomoto, Ise-shi, Mie (JP)

(73) Assignee: MURATA MACHINERY, LTD., Kyoto-shi, Kyoto (JP)

(21) Appl. No.: 18/708,134

(22) PCT Filed: Sep. 30, 2022
(86) PCT No.: PCT/JP2022/036749

§ 371 Date: May 7, 2024

(30) Foreign Application Priority Data
Nov. 11, 2021 (JP) 2021-184132

(51) Int. Cl. H01L 21/677; H01L 21/67; H01L 21/687

(52) U.S. Cl. CPC H01L 21/67733; H01L 21/67259; H01L 21/67736; H01L 21/68707

(57) ABSTRACT

An overhead transport vehicle includes: a traveling part configured to travel along a traveling rail; a lifting part provided in the traveling part; a gripper unit configured to be raised and lowered by the lifting part and grip an article; an accelerometer mounted on the gripper unit; and a control device configured to recognize a lifting operation state of the gripper unit and determine presence or absence of an abnormality in the gripper unit based on the lifting operation state and a detection result of the accelerometer.

### CROSS-REFERENCE TO RELATED APPLICATIONS

This application is a US national stage filing under 35 U.S.C. § 371 of International Application No. PCT/JP2022/036749, filed Sep. 30, 2022, which claims priority to Japanese Patent Application No. 2021-184132, filed Nov. 11, 2021, each of which is incorporated herein by reference in its entirety.

### TECHNICAL FIELD

This disclosure relates to an overhead transport vehicle.

### BACKGROUND

Overhead transport vehicles configured to travel along a traveling rail to convey containers are known. An overhead transport vehicle described in WO 2018/179931 includes a traveling part configured to travel along a traveling rail, a lifting part provided in the traveling part, and a holding part configured to be raised and lowered by the lifting part and hold a flange part that a container has. The holding part has a center cone as a positioning section that fits into a recess formed in the flange part. The center cone is freely raised and lowered with respect to the holding part, and a relative upward movement of the center cone with respect to the holding part is detected by a detection section. The control section recognizes that the holding part has reached a height position at which a gripping operation is to be performed, based on the relative upward movement (or an amount of upward movement) of the center cone. At that height position, the control section stops lowering of the holding part and causes the holding part to execute a gripping operation.

For example, a container may fail to be placed in a proper position on a placing surface. As illustrated in FIG. 9(a), if a container 90 is misaligned with respect to a gripper unit (holding part) 6 to be lowered, the center cone 8 may fail to fit into a recess 91a and may contact other parts of a flange part 91 (see FIG. 9(b)). Even in such an example, the relative upward movement of the center cone 8 with respect to the gripper unit 6 may be detected and a gripping operation may be started (see FIG. 9(c)). In this example, claw members 6a of the gripper unit 6 do not enter a side under the flange part 91. Therefore, various errors can occur before the gripper unit 6 rises, and it is desirable to be able to detect such errors in the gripper unit 6 before the gripping operation is started.

It could therefore be helpful to provide an overhead transport vehicle that can reliably detect abnormalities at, for example, the start of gripping operation in the gripper unit.

### SUMMARY

We thus provide:

An overhead transport vehicle includes: a traveling part configured to travel along a traveling rail; a lifting part provided in the traveling part; a gripper unit configured to be raised and lowered by the lifting part and grip an article; an accelerometer mounted on the gripper unit; and a control device configured to recognize a lifting operation state of the gripper unit and determine presence or absence of an abnormality in the gripper unit based on the lifting operation state and a detection result of the accelerometer.

According to this overhead transport vehicle, the accelerometer detects acceleration or the like that occurs in the gripper unit. The control device determines presence or absence of an abnormality in the gripper unit based on the lifting operation state of the gripper unit and the detection result of the accelerometer. When only the detection result of the accelerometer is used, there is a possibility of determining that an abnormality has occurred even though the gripper unit is operating normally, but by taking into account the lifting operation state of the gripper unit, presence or absence of an abnormality in the gripper unit can be reliably detected.

The control device may determine presence or absence of an abnormality in the gripper unit based on whether the detected value of the accelerometer in a state where the gripper unit is stopped at a gripping position exceeds a first set value that has been preset. Thus, whether there is no problem with starting the gripping operation can be reliably detected. For example, when the gripper unit is to grip an article, excessive impact on the article, or a like failure can be avoided.

The control device may determine presence or absence of an abnormality in the gripper unit based on whether the detected value of the accelerometer during lifting operation of the gripper unit exceeds a second set value that has been preset. Thus, whether there is no problem with continuing the lifting operation can be reliably detected. For example, when the gripper unit rises or lowers, excessive impact on the article, or a like failure can be avoided.

The accelerometer may be capable of detecting acceleration of the gripper unit in at least a vertical direction. Thus, shaking or impact in the vertical direction in the gripper unit can be detected.

The accelerometer may be capable of detecting acceleration of the gripper unit in a first horizontal direction and a second horizontal direction that each are orthogonal to the vertical direction and are orthogonal to each other. Thus, shaking or impact in the horizontal direction in the gripper unit can also be detected. Inclination of the gripper unit can also be detected during a stopped state of the gripper unit.

In the overhead transport vehicle, an abnormality in the gripper unit can be reliably detected.

### BRIEF DESCRIPTION OF THE DRAWINGS

FIG. 1 is a side view of an overhead transport vehicle according to an example.

FIG. 2 is a functional block diagram of a control device in the overhead transport vehicle.

FIG. 3 is a diagram illustrating a detection state of presence or absence of an abnormality in gripping control of a gripper unit.

FIG. 4 is a flow diagram representing processing steps in the gripping control of the gripper unit.

FIG. 5 is a diagram illustrating a detection state of presence or absence of an abnormality in rising control during load grabbing of the gripper unit.

FIG. 6 is a flow diagram representing processing steps in the rising control during load grabbing of the gripper unit.

FIG. 7 is a diagram illustrating a detection state of presence or absence of an abnormality in lowering control during unloading of the gripper unit.

FIG. 8 is a flow diagram representing processing steps in the lowering control during unloading of the gripper unit.

FIGS. 9(a) to 9(c) are diagrams each illustrating an example of when the gripping control is not properly performed due to misalignment of an article or other reasons.

### REFERENCE SIGNS LIST

1 . . . overhead transport vehicle
2 . . . traveling part
5 . . . lifting part
6 . . . gripper unit
6a . . . claw member
7 . . . control device
8 . . . center cone
9 . . . accelerometer
20 . . . flange detection section
36 . . . abnormality determination section
37 . . . lifting control section
38 . . . gripping control section
40 . . . shaking detection section
90 . . . . FOUP (article)
101 . . . traveling rail
P1 . . . gripping position
P2 . . . deceleration start position during rising
P3 . . . deceleration start position during lowering

### DETAILED DESCRIPTION

Examples will now be described with reference to the drawings. In the description of the drawings, like elements are designated by like reference signs, and duplicate description is omitted.

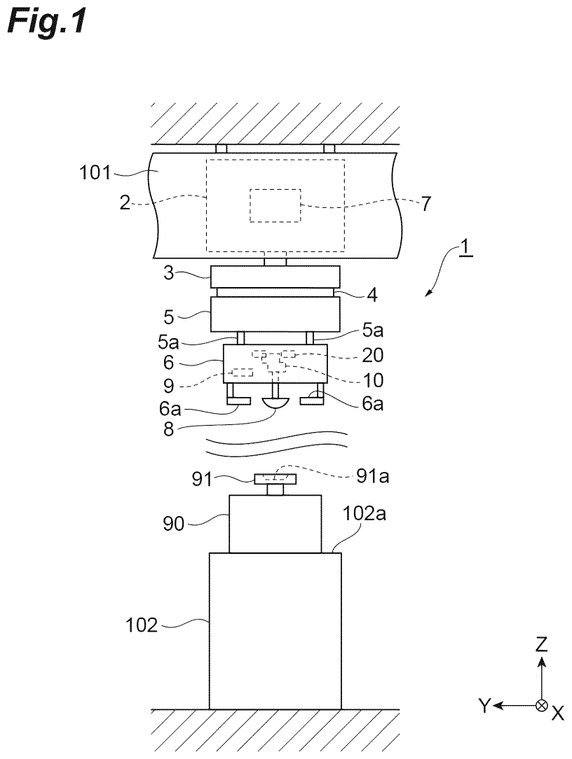

As illustrated in FIG. 1, an overhead transport vehicle 1 travels along a traveling rail 101 laid near a ceiling of a clean room where semiconductor devices are manufactured. The overhead transport vehicle 1 conveys a FOUP (article) 90 that is a container in which a plurality of semiconductor wafers are housed. The overhead transport vehicle 1 transfers the FOUP 90 to a load port (transfer destination) 102 provided in a processing apparatus configured to provide various types of processing on the semiconductor wafers. In other words, the overhead transport vehicle 1 collects the FOUP 90 disposed on a placing surface 102a of the load port 102 or disposes the FOUP 90 on the placing surface 102a of the load port 102.

The overhead transport vehicle 1 includes a traveling part 2, a horizontal feed part 3, a turning part 4, a lifting part 5, a gripper unit 6, and a control device 7. The traveling part 2, for example, travels along the traveling rail 101 by receiving supply of electric power in a contactless manner from a high-frequency current line laid along the traveling rail 101. The horizontal feed part 3 moves the turning part 4, the lifting part 5, and the gripper unit 6 in a lateral direction with respect to a direction in which the traveling rail 101 extends. The turning part 4 turns the lifting part 5 and the gripper unit 6 in the horizontal plane. The lifting part 5 has a plurality of belts (suspending members) 5a, and the gripper unit 6 is attached to lower ends of the belts 5a. The lifting part 5 raises and lowers the gripper unit 6 by unrolling or winding the plurality of belts (suspension members) 5a. The gripper unit 6 grips the flange part 91 included in the FOUP 90 by closing a pair of claw members 6a. The gripper unit 6 releases a gripped state of the flange part 91 by opening the pair of claw members 6a. The control device 7 is an electronic control unit including a CPU (processor), a ROM, a RAM and the like. The control device 7 controls operations of each part of the overhead transport vehicle 1.

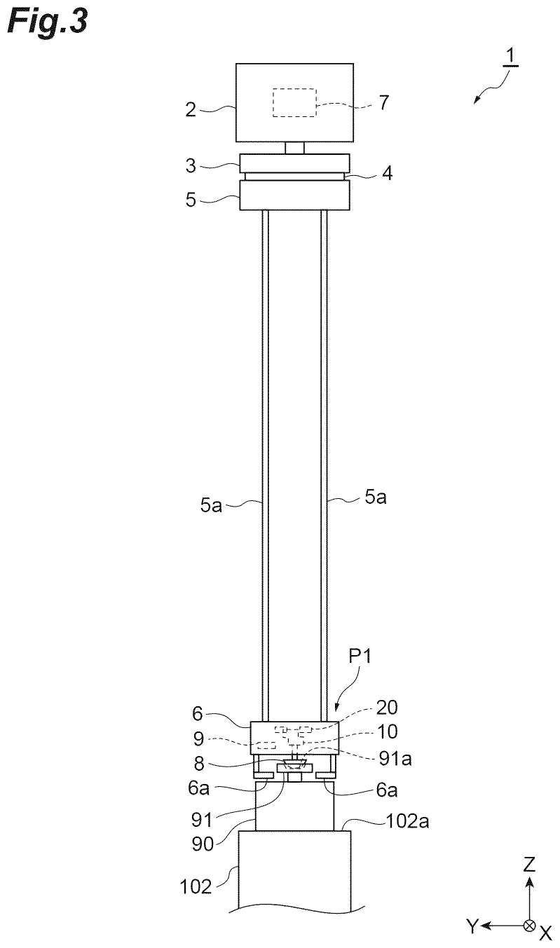

XYZ axes are also described in FIG. 1. The Y direction in FIG. 1 is a traveling direction of the overhead transport vehicle 1, and the X direction in FIG. 1 is a lateral movement direction in which the gripper unit 6 or the like are moved by the horizontal feed part 3. The Z direction in FIG. 1 is a vertical direction. The overhead transport vehicle 1 lowers the gripper unit 6 along the Z direction and raises the gripper unit 6 along the Z direction. The traveling direction (Y direction; first horizontal direction) of the overhead transport vehicle 1 and the lateral movement direction (X direction; second horizontal direction) by the horizontal feed part 3 are each orthogonal to the vertical direction (Z direction) and are orthogonal to each other. The XYZ axes are also printed in FIGS. 3, 5, and 7, which are referenced in the descriptions below.

The overhead transport vehicle 1 further includes a center cone (positioning section) 8, a dog 10, and a flange detection section 20. A recess 91a, open upward, is formed in the center of the flange part 91 of the FOUP 90. The center cone 8 is a member to fit into the recess 91a of the flange part 91 for positioning of the gripper unit 6 with respect to the FOUP 90. The center cone 8, the dog 10, and the flange detection section 20 are provided on the gripper unit 6. The center cone 8, the dog 10, and the flange detection section 20 are attached on a base (not illustrated) of the gripper unit 6. The center cone 8 is energized downward by a spring (not illustrated) attached on the base, and is freely moved up and down with respect to the gripper unit 6.

When performing load grabbing for the FOUP 90 placed on the load port 102, lowering control is performed for the gripper unit 6 by the control device 7, and the center cone 8 fits into the recess 91a of the flange part 91. When the gripper unit 6 further lowers due to its own weight, the center cone 8 relatively rises with respect to the gripper unit 6. With the photo interrupter including a light emitter and a light receiver of the flange detection section 20 and a light shield plate of the dog 10 that passes across the optical axis of the photo interrupter, the control device 7 recognizes that the gripper unit 6 has reached a gripping position P1 (see FIG. 3). The control device 7 stops the lowering of the gripper unit 6 and causes the gripper unit 6 to close the pair of claw members 6a. When the claw members 6a close, the claw members 6a enter the side under the flange part 91. The control device 7 then starts raising of the gripper unit 6 by the lifting part 5. When the gripper unit 6 holding the FOUP 90 disposes the FOUP 90 on the placing surface 102a of the load port 102, i.e., operation during unloading is the opposite of that during load grabbing.

Recognition of the position of the gripper unit 6 using the center cone 8, the dog 10 and the flange detection section 20 and recognition of the gripped state of the FOUP 90 caused by the gripper unit 6 are implemented, for example, by a configuration and a method described in WO 2018/179931. However, other known configurations and methods may be used for the recognition of the position of the gripper unit 6 and the recognition of the gripped state of the FOUP 90 caused by the gripper unit 6.

The lifting part 5 has a lifting motor (not illustrated), and lowers the gripper unit 6 by causing the lifting motor to unroll the belt 5a, and the raises the gripper unit 6 by causing the lifting motor to wind up the belt 5a. The lifting motor is driven and controlled by the control device 7. The control device 7 can detect the amount of unrolling the belt 5a (belt length) by receiving signals related to rotation from the lifting motor. The control device 7 can detect the position (height position) of the gripper unit 6 based on the amount of unrolling the belt 5a (belt length).

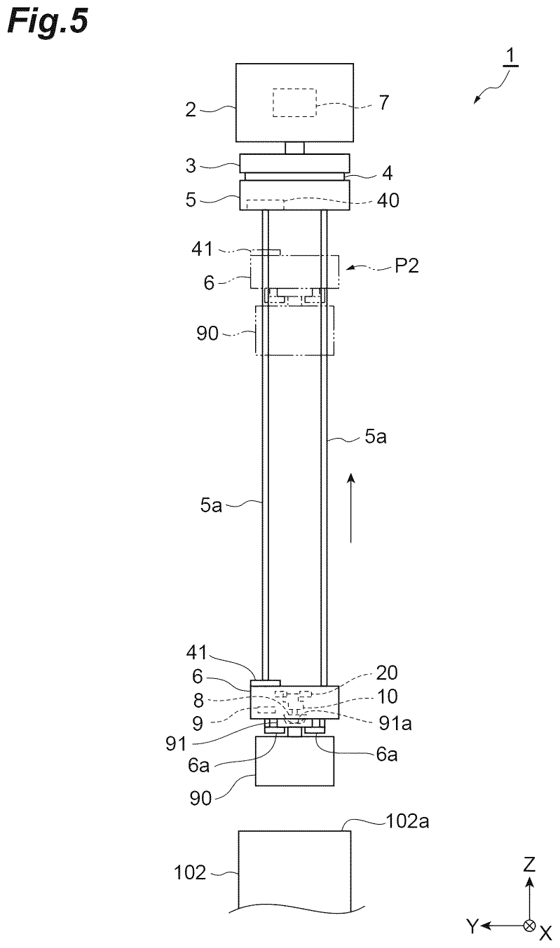

As illustrated in FIG. 5, the overhead transport vehicle 1 includes a shaking detection section 40 configured to detect shaking of the gripper unit 6. The shaking detection section 40 is attached, for example, to the lifting part 5. The shaking detection section 40, for example, has a light emitter and a light receiver, and the light emitter and the light receiver are exposed downward. On the other hand, a reflector 41 is attached to a top surface of the gripper unit 6. With the gripper unit 6 hanging straight down (i.e., the belt 5a extends in the vertical direction) as a reference, emitting light downward and detecting reflected light reflected by the reflector 41, the shaking detection section 40 can detect that the gripper unit 6 is not shaking. In other words, if the reflected light is not detected (the reflected light is failed to be detected), the shaking detection section 40 can detect that the gripper unit 6 is shaking more than a predetermined amount. The shaking detection section 40 outputs (transmits) a detection result of the shaking of the gripper unit 6 to the control device 7.

Next, a configuration for detecting abnormalities in the gripper unit 6 (for example, inclination, shaking, impact or the like that occurs in the gripper unit 6) is described. The gripper unit 6 has an accelerometer 9 mounted thereon (see FIG. 1). The accelerometer 9 is attached on the base of the gripper unit 6, for example. The accelerometer 9 is, for example, a three-axis acceleration sensor capable of detecting acceleration in each of the Z, X, and Y directions. A type of the accelerometer 9 is not particularly limited. As the accelerometer 9, for example, a capacitive sensor may be applied, or a piezoresistive sensor may be applied. The gripper unit 6 may have three single-axis acceleration sensors mounted thereon that are capable of detecting acceleration in the Z, X, and Y directions, respectively.

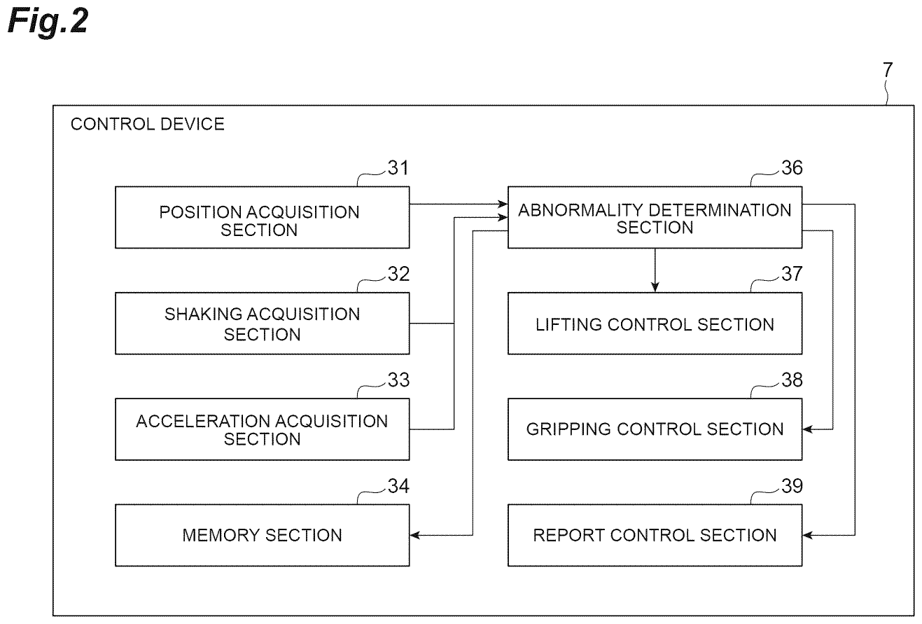

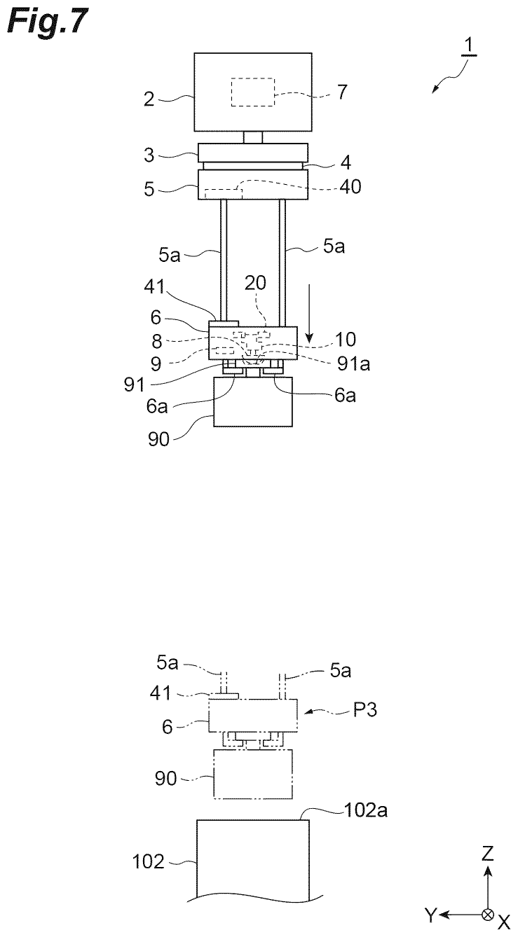

The control device 7 determines presence or absence of an abnormality in the gripper unit 6. With reference to FIG. 2, each function included in the control device 7 is explained. FIG. 2 is a functional block diagram of the control device 7 in the overhead transport vehicle 1. The control device 7 has a position acquisition section 31, a shaking acquisition section 32, an acceleration acquisition section 33, a memory section 34, and an abnormality determination section 36. Signals output from the lifting motor of the belt 5a and the flange detection section 20 are input to the position acquisition section 31, and the position acquisition section 31 acquires the position (height position) of the gripper unit 6 based on the input signals. By acquiring the position of the gripper unit 6, the position acquisition section 31 recognizes the lifting operation state of the gripper unit 6. The lifting operation state of the gripper unit 6 includes a state in which the gripper unit 6 is stopped at the gripping position P1 (see FIG. 3), a state in which the gripper unit 6 is rising, and a state in which the gripper unit 6 is lowered. While the gripper unit 6 is rising, the position acquisition section 31 monitors that the gripper unit 6 reaches a deceleration start position P2 (see FIG. 5) or the like during rising. While the gripper unit 6 is lowering, the position acquisition section 31 monitors that the gripper unit 6 reaches the deceleration start position P3 (see FIG. 7) or the like during lowering. The signal output from the shaking detection section 40 is input to the shaking acquisition section 32, and the shaking acquisition section 32 acquires the shaking (amount of shaking) of the gripper unit 6. Signals output from the accelerometer 9 in the gripper unit 6 are input to the acceleration acquisition section 33, and the acceleration acquisition section 33 acquires acceleration that occurs in the gripper unit 6.

The abnormality determination section 36 determines presence or absence of an abnormality in the gripper unit 6 based on the lifting operation state of the gripper unit 6 and the detection result of the accelerometer 9. The memory section 34 stores various thresholds used in the abnormality determination section 36. More precisely, the memory section 34 stores the first set value, which is a threshold for determining presence or absence of an abnormality in the gripper unit 6 in a state where the gripper unit 6 is stopped at the gripping position P1 (see FIG. 3). The first set value is, for example, a threshold for the acceleration of the gripper unit 6 in the Z direction (inclination with respect to the Z direction). The memory section 34 also stores the second set value, which is a threshold for determining presence or absence of an abnormality in the gripper unit 6 during lifting operation of the gripper unit 6 (lifting state). The second set value is, for example, a threshold for the acceleration of the gripper unit 6 in the Z direction. The second set value may be, for example, a threshold for the acceleration of the gripper unit 6 in the X direction and/or the Y direction.

The control device 7 further includes a lifting control section 37, a gripping control section 38, and a reporting control section 39. The lifting control section 37 controls the lifting motor of the lifting part 5, to lower, stop, or raise the gripper unit 6. The gripping control section 38 performs open/close control for the claw members 6a of the gripper unit 6 when the position acquisition section 31 recognizes that the gripper unit 6 is located at the gripping position P1. The reporting control section 39 activates a reporting device such as an alarm or the like, for example, installed in a host controller or the like to report an error when the abnormality determination section 36 determines that an error occurs in the gripper unit 6.

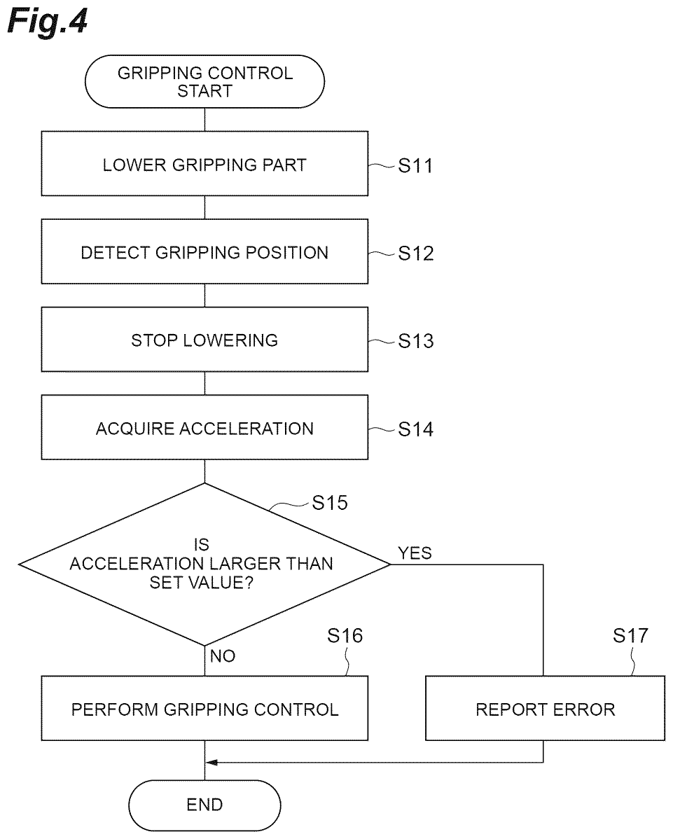

With reference to FIG. 3 and thereafter, the following describes a determination method for presence or absence of an abnormality in the gripper unit 6 in various lifting operation states of the overhead transport vehicle 1. FIG. 3 is a diagram illustrating a detection state of presence or absence of an abnormality in a gripping control of the gripper unit 6. FIG. 4 is a flow diagram representing the processing procedures in the gripping control. As illustrated in FIGS. 3 and 4, the lifting control section 37 performs lowering control for the gripper unit 6 in a state of gripping (holding) the FOUP 90 (step S11). The position acquisition section 31 then recognizes that the gripper unit 6 is located at the gripping position P1, based on a signal output from the flange detection section 20 (step S12). The lifting control section 37 stops and controls the lowering of the gripper unit 6 (step S13). In a state where the gripper unit 6 is stopped at the gripping position P1, the acceleration acquisition section 33 acquires a detected value of acceleration output from the accelerometer 9 (step S14). The abnormality determination section 36 determines whether the detected value in the accelerometer 9 exceeds the first set value that has been preset (step S15).

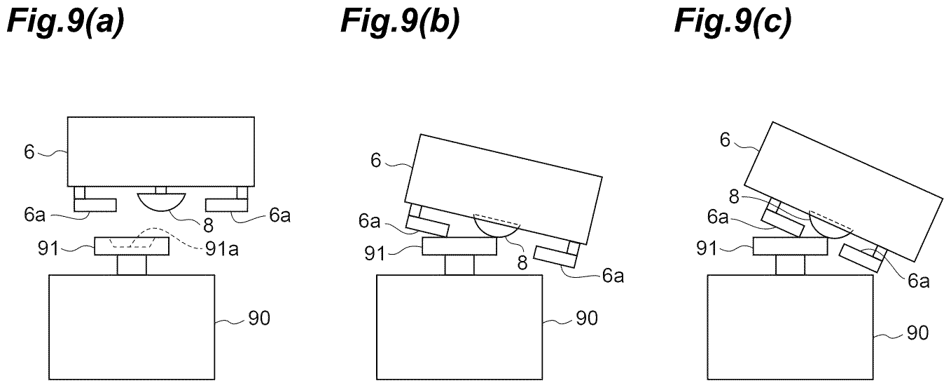

When the gripper unit 6 is located directly above the FOUP 90 and the center cone 8 is properly fitted into the recess 91a of the flange part 91, the gripper unit 6 maintains a substantially horizontal posture (see FIG. 3). In such a configuration, the detected value in the accelerometer 9 is less than or equal to the first set value, and the abnormality determination section 36 determines that there is no abnormality (step S15; NO). Then, the gripping control section 38 performs gripping control for the gripper unit 6 and causes the claw members 6a to close to perform the gripping operation (step S16). In the gripping operation, the claw members 6a of the gripper unit 6 enter the side under the flange part 91. On the other hand, when, for example, a mating failure occurs as illustrated in FIG. 9(b), the detected value in the accelerometer 9 will exceed the first set value, and the abnormality determination section 36 determines that there is an abnormality (step S15; YES). The reporting control section 39 then controls the reporting device to report an error (step S17).

Through the above-described series of control, the gripping control in the gripper unit 6 is executed. When the gripping control cannot be performed properly due to misalignment of the FOUP 90, or for other reasons, the gripper unit 6 is inclined, which is detected by the accelerometer 9, and thus the gripping operation is not executed (i.e., the claw members 6a are not closed) and an error is reported. The first set value is set to a value corresponding to inclination that is greater than a maximum inclination of the gripper unit 6 that can occur with the center cone 8 properly fitted.

In the overhead transport vehicle 1, the accelerometer 9 detects acceleration or the like that occurs in the gripper unit 6. The control device 7 determines presence or absence of an abnormality in the gripper unit 6 based on the lifting operation state of the gripper unit 6 and the detection result of the accelerometer 9. When only the detection result of the accelerometer 9 is used, there may be determined that an error has occurred although the gripper unit 6 is operating normally. However, presence or absence of an abnormality in the gripper unit 6 can be reliably detected by taking into account the lifting operation state of the gripper unit 6 (the stopped state in the above example).

The control device 7 determines presence or absence of an abnormality in the gripper unit 6 based on whether a detected value of the accelerometer 9 in a state where the gripper unit 6 is stopped at the gripping position P1 exceeds the first set value that has been preset. Therefore, whether there is no problem with starting the gripping operation can be reliably detected. For example, when the gripper unit 6 is to grip the FOUP 90, excessive impact on the FOUP 90, or a like failure can be avoided.

The accelerometer 9 can detect the acceleration of the gripper unit 6 in the Z, X and Y directions. Therefore, inclination of the gripper unit 6 can be detected during stopped state of the gripper unit 6.

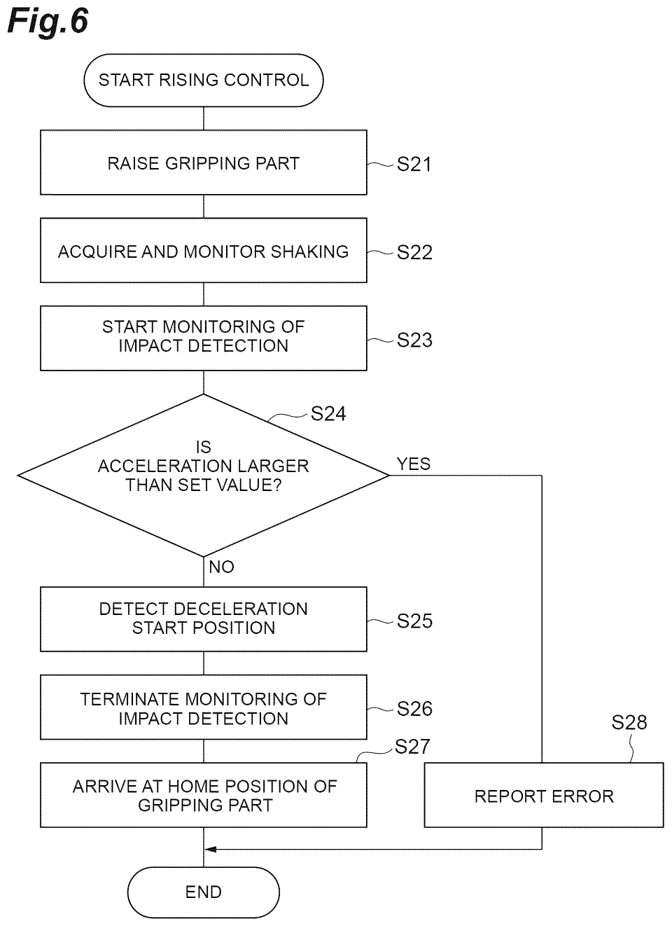

With reference to FIGS. 5 and 6, the following describes a determination method for presence or absence of an abnormality in the gripper unit 6 in a rising state of the gripper unit 6. FIG. 5 is a diagram illustrating a detection state of presence or absence of an abnormality in the rising control of the gripper unit 6 during load grabbing. FIG. 6 is a flow diagram representing the processing steps in the rising control. As illustrated in FIGS. 5 and 6, the lifting control section 37 performs rising control for the gripper unit 6 in a state of gripping (holding) the FOUP 90 (step S21). After the gripper unit 6 starts rising, acquisition and monitoring of shaking by the shaking acquisition section 32 is executed (step S22), and monitoring of impact detection by the acceleration acquisition section 33 and the abnormality determination section 36 is started (step S23). While light emission and reception at the shaking detection section 40 and the reflector 41 is established, no error is reported by the shaking acquisition section 32. However, even when such shaking is within a permissible range, an impact or vibration or the like may be applied to the gripper unit 6 during rising. When the acceleration acquisition section 33 acquires the detected value of acceleration output from the accelerometer 9 in step S23, the abnormality determination section 36 determines whether the detected value in the accelerometer 9 exceeds the second set value that has been preset (step S24).

When the abnormality determination section 36 determines that the detected value in the accelerometer 9 is less than or equal to the second set value (step S24; NO), the rising control of the gripper unit 6 continues, and the position acquisition section 31 recognizes that the gripper unit 6 is at the deceleration start position P2 during rising (step S25). The deceleration start position P2 during rising may be recognized by a sensor (not illustrated) configured to detect that the gripper unit 6 has risen to the vicinity of the lifting part 5, as indicated by a virtual line in FIG. 5. When the gripper unit 6 reaches the deceleration start position P2 during rising, the abnormality determination section 36 terminates the monitoring of impact detection (step S26). Then, the gripper unit 6 is further raised by the lifting control section 37 at a reduced lifting speed, and the gripper unit 6 arrives at a home position (rising end) (step S27).

When an impact or vibration or the like is applied to the gripper unit 6 during rising, in step S24, the abnormality determination section 36 determines that the detected value in the accelerometer 9 exceeds the second set value (step S24; YES), and the reporting control section 39 controls the reporting device to report an error (step S28).

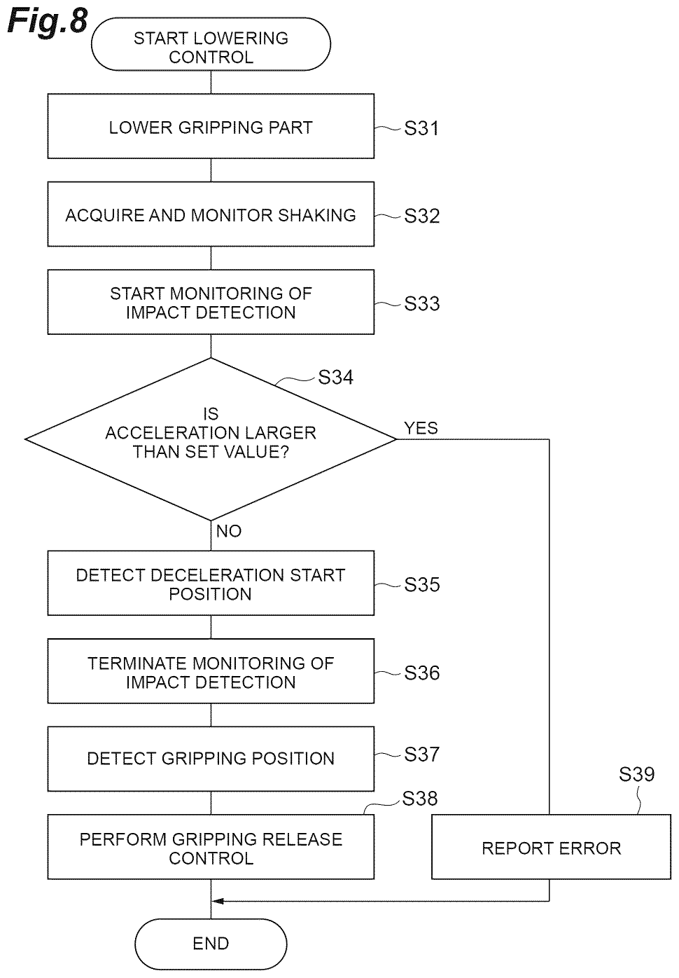

With reference to FIGS. 7 and 8, the following describes a determination method for presence or absence of an abnormality in the gripper unit 6 in a lowering state of the gripper unit 6. FIG. 7 is a diagram illustrating a detection state of presence or absence of an abnormality in the lowering control of the gripper unit 6 during unloading. FIG. 8 is a flow diagram representing the processing steps in the lowering control. As illustrated in FIGS. 7 and 8, the lifting control section 37 performs lowering control for the gripper unit 6 in a state of gripping (holding) the FOUP 90 (step S31). After the gripper unit 6 starts lowering, acquisition and monitoring of shaking by the shaking acquisition section 32 is executed (step S32), and the monitoring of impact detection by the acceleration acquisition section 33 and the abnormality determination section 36 is started (step S33). While light emission and reception at the shaking detection section 40 and the reflector 41 is established, no error is reported by the shaking acquisition section 32. However, even when such shaking is within the permissible range, an impact or vibration or the like may be applied to the gripper unit 6 during lowering. When the acceleration acquisition section 33 acquires the detected value of acceleration output from the accelerometer 9 in step S33, the abnormality determination section 36 determines whether the detected value in the accelerometer 9 exceeds the second set value that has been preset (step S34).

The second set value in the lowering control (control during unloading) is the same as the second set value in the rising control (control during load grabbing) described above, but these may be different from each other. The second set value in the lowering control may be smaller than the second set value in the rising control. The second set value in the lowering control may be greater than the second set value in the rising control. The second set value is set to a value above a range of predetermined acceleration of the gripper unit 6 that can occur in normal rising control or normal lowering control of the gripper unit 6.

If the abnormality determination section 36 determines that the detected value in the accelerometer 9 is less than or equal to the second set value (step S34; NO), the lowering control of the gripper unit 6 continues, and the position acquisition section 31 recognizes that the gripper unit 6 is located at the deceleration start position P3 during lowering (step S35). The deceleration start position P3 during lowering is a transition start position to auto-teaching or creep control as indicated by a virtual line in FIG. 7, and is set somewhat higher than the gripping position P1 described above. When the gripper unit 6 reaches the deceleration start position P3 during lowering, the abnormality determination section 36 terminates the monitoring of impact detection (step S36). Thereafter, the lifting control section 37 causes the gripper unit 6 to lower further at a decelerated lowering speed, and the position acquisition section 31 recognizes that the gripper unit 6 is at the gripping position P1 (step S37). Then, the gripping control section 38 performs release control for the gripper units 6, and causes the claw members 6a to open to release the gripped state caused by the gripper unit 6 (step S38).

When an impact or vibration or the like is applied to the gripper unit 6 during lowering, in step S34, the abnormality determination section 36 determines that the detected value in the accelerometer 9 exceeds the second set value (step S34; YES), and the reporting control section 39 controls the reporting device to report the error (step S39).

In the overhead transport vehicle 1, the accelerometer 9 detects acceleration or the like that occurs in the gripper unit 6. The control device 7 determines presence or absence of an abnormality in the gripper unit 6 based on the lifting operation state of the gripper unit 6 and the detection result of the accelerometer 9. When only the detection result of the accelerometer 9 is used, there may be determined that an abnormality has occurred even though the gripper unit 6 is operating normally. However, presence or absence of an abnormality in the gripper unit 6 can be reliably detected by taking into account the lifting operation state of the gripper unit 6 (rising state or lowering state in the above example).

The control device 7 determines presence or absence of an abnormality in the gripper unit 6 based on whether the detected value of the accelerometer 9 during lifting operation of the gripper unit 6 exceeds the second set value that has been preset. Therefore, whether there is no problem with continuing the lifting operation can be reliably detected. For example, when the gripper unit 6 rises or lowers, excessive impact on the FOUP 90, or a like failure can be avoided.

The accelerometer 9 can detect the acceleration of the gripper unit 6 in the Z, X and Y directions. Therefore, shaking or impact or the like in the horizontal direction in the gripper unit 6 can also be detected.

Although an example has been described above, this disclosure is not limited to the above example. For example, the configuration of accelerometer 9 is not limited to the three-axis acceleration sensor in the above example. A single-axis acceleration sensor capable of detecting acceleration in the Z direction may be mounted on the gripper unit 6. Even in this configuration, an abnormality (shaking or impact or the like) in the Z direction occurring in the gripper unit 6 can be detected.

A detection section the type of which is different from that in the above example may be employed as the flange detection section 20. The relative upward movement of the center cone 8 with respect to the gripper unit 6 may be detected by a configuration different from that in the flange detection section 20. A positioning part other than the center cone 8 may be applied as long as the positioning part is fitted into some recess formed in the flange part 91 of the FOUP 90. The articles transported by the overhead transport vehicle 1 may be containers or other items other than the FOUP 90.

The lowering control of the gripper unit 6 described in FIGS. 7 and 8 is not limited to unloading control, but may be applied when auto-teaching is performed.

Configuration requirements of one aspect of this disclosure are described as follows.
(1) An overhead transport vehicle includes:
a traveling part configured to travel along a traveling rail;
a lifting part provided in the traveling part;
a gripper unit configured to be raised and lowered by the lifting part and grip an article;
an accelerometer mounted on the gripper unit; and
a control device configured to recognize a lifting operation state of the gripper unit and determine presence or absence of an abnormality in the gripper unit based on the lifting operation state and a detection result of the accelerometer.
(2) The overhead transport vehicle according to (1), in which the control device determines presence or absence of an abnormality in the gripper unit based on whether the detected value of the accelerometer in a state where the gripper unit is stopped at a gripping position exceeds a first set value that has been preset.
(3) The overhead transport vehicle according to (1) or (2), in which the control device determines presence or absence of an abnormality in the gripper unit based on whether the detected value of the accelerometer during lifting operation of the gripper unit exceeds a second set value that has been preset.
(4) The overhead transport vehicle according to any one of (1) to (3), in which the accelerometer is capable of detecting acceleration of the gripper unit in at least a vertical direction.
(5) The overhead transport vehicle according to (4), in which the accelerometer is capable of detecting the acceleration of the gripper unit in a first horizontal direction and a second horizontal direction that each are orthogonal to the vertical direction and are orthogonal to each other.

1.-5. (canceled)

6. An overhead transport vehicle comprising:
a traveling part configured to travel along a traveling rail;
a lifting part provided in the traveling part;
a gripper unit configured to be raised and lowered by the lifting part and grip an article;
an accelerometer mounted on the gripper unit; and
a control device configured to recognize a lifting operation state of the gripper unit and determine presence or absence of an abnormality in the gripper unit based on the lifting operation state and a detection result of the accelerometer,
wherein the control device determines presence or absence of an inclination of the gripper unit with respect to a vertical direction as an abnormality in the gripper unit based on whether the detected value of the accelerometer in a state where the gripper unit is stopped at a gripping position exceeds a first set value for the inclination of the gripper unit that has been preset.

7. The overhead transport vehicle according to claim 6, wherein the accelerometer is capable of detecting acceleration of the gripper unit in at least the vertical direction.

8. The overhead transport vehicle according to claim 7, wherein the accelerometer is capable of detecting the acceleration of the gripper unit in a first horizontal direction and a second horizontal direction that each are orthogonal to the vertical direction and are orthogonal to each other.
